(19) United States
(12) Patent Application Publication
(10) Pub. No.: US 2024/0130161 A1
(43) Pub. Date: Apr. 18, 2024

(54) DISPLAY PANEL

(71) Applicant: Samsung Display Co., Ltd., Yongin-si (KR)

(72) Inventor: INYOUNG JUNG, Yongin-si (KR)

(21) Appl. No.: 18/450,801

(22) Filed: Aug. 16, 2023

(30) Foreign Application Priority Data
Oct. 14, 2022 (KR) 10-2022-0132215

(51) Int. Cl. H10K 59/121; H10K 59/122; H10K 59/123; H10K 59/88

(52) U.S. Cl. CPC H10K 59/1216; H10K 59/1213; H10K 59/122; H10K 59/123; H10K 59/88

(57) ABSTRACT

A display panel includes: a base layer; a circuit layer on the base layer and comprising a pixel circuit; and a light emitting element layer on the circuit layer, wherein the light emitting element layer comprises: a first electrode on the circuit layer; a light emitting pattern on the first electrode; a second electrode on the light emitting pattern; and an upper pixel definition layer on the circuit layer and having an upper opening defined therein, the upper pixel definition layer comprises a first part electrically connected to the second electrode and a second part electrically insulated from the first part, and the second part is surrounded by the first part in a plan view.

### CROSS-REFERENCE TO RELATED APPLICATIONS

The present application claims priority to and the benefit of Korean Patent Application No. 10-2022-0132215, filed on Oct. 14, 2022, the entire contents of which are hereby incorporated by reference.

### BACKGROUND

### 1. Field

Aspects of some embodiments of the present disclosure herein relate to a display panel.

### 2. Description of the Related Art

A display panel is used in various multimedia devices such as televisions, mobile phones, tablet computers, or game machines in order to provide image information. A display panel generally includes light emitting elements and pixel circuits for driving the light emitting elements. The light emitting elements included in the display panel emit light and generate images in response to voltages applied from the pixel circuits.

The above information disclosed in this Background section is only for enhancement of understanding of the background and therefore the information discussed in this Background section does not necessarily constitute prior art.

### SUMMARY

Aspects of some embodiments of the present disclosure herein relate to a display panel, and for example, to a display panel that may use a portion of a pixel definition layer as a capacitor electrode to reduce the area of a pixel circuit.

Aspects of some embodiments of the present disclosure include a display panel having a relatively small pixel circuit area.

According to some embodiments of the present disclosure, a display panel includes: a base layer; a circuit layer including a pixel circuit and on the base layer; and a light emitting element layer on the circuit layer, wherein the light emitting element layer includes: a first electrode on the circuit layer; a light emitting pattern on the first electrode; a second electrode on the light emitting pattern; and an upper pixel definition layer having an upper opening defined therein and on the circuit layer, wherein the upper pixel definition layer includes a first part electrically connected to the second electrode and a second part electrically insulated from the first part, and the second part is surround by the first part in a plan view.

According to some embodiments, the circuit layer may further include a connection metal electrically connected to the second part.

According to some embodiments, the light emitting element layer may further include a lower pixel definition layer having a light emitting area defined therein and under the upper pixel definition layer.

According to some embodiments, the circuit layer may further include a first cap metal overlapping at least a portion of the second part in a plan view and under the second part.

According to some embodiments, the pixel circuit may include: a driving transistor; and a capacitor connected between a gate electrode of the driving transistor and a driving voltage line to which a driving voltage is provided, and the second part and the first cap metal may constitute the capacitor.

According to some embodiments, the circuit layer may further include at least one insulation layer under the first electrode and under the lower pixel definition layer, wherein each of the at least one insulation layer and the lower pixel definition layer overlaps at least a portion of the second part in a plan view.

According to some embodiments, an opening may be defined in the lower pixel definition layer, and the second part may contact the at least one insulation layer exposed by the opening of the lower pixel definition layer.

According to some embodiments, a distance between the first cap metal and the first part may be larger than that between the first cap metal and the second part.

According to some embodiments, the circuit layer may further include a second cap metal overlapping at least a portion of the first cap metal in a plan view and under the first cap metal.

According to some embodiments, an identical signal may be provided to the second cap metal and the second part.

According to some embodiments, the first cap metal may include a 1-1st cap metal, and a 1-2nd cap metal connected to the 1-1st cap metal and on a different layer from the 1-1st cap metal.

According to some embodiments, the display panel may further include an encapsulation layer including an organic encapsulation layer and on the light emitting element layer, wherein the organic encapsulation layer fills a space between the first part and the second part and covers the light emitting element layer.

According to some embodiments, the upper pixel definition layer may include a first conductive layer and a second conductive layer on the first conductive layer.

According to some embodiments, in the first part, a side surface of the second conductive layer may be further protruded toward a central direction of the light emitting area than a side surface of the first conductive layer.

According to some embodiments, the display panel may further include: a protection pattern configured to cover at least a portion of a top surface of the first electrode.

According to some embodiments of the present disclosure, a display panel includes: a base layer; a circuit layer including a pixel circuit and on the base layer; a light emitting element layer on the circuit layer; and an encapsulation layer on the light emitting element layer, wherein the pixel circuit include: a driving transistor; and a capacitor connected between a gate electrode of the driving transistor and a driving voltage line to which a driving voltage is provided, and wherein the light emitting element layer include: a first electrode on the circuit layer and electrically connected to the pixel circuit; a light emitting pattern on the first electrode; a second electrode on the light emitting pattern; and an upper pixel definition layer having an upper opening defined therein and on the circuit layer, wherein the upper pixel definition layer include a first part electrically connected to the second electrode and a second part constituting the capacitor.

According to some embodiments, a slit may be defined between the first part and the second part of the upper pixel definition layer, and a shape of the slit is a polygon or a ring in a plan view.

According to some embodiments, the encapsulation layer may include an organic encapsulation layer, and the slit may be filled with the organic encapsulation layer.

According to some embodiments, the circuit layer may further include a connection metal electrically connected to the second part.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain principles of some embodiments according to the present disclosure. In the drawings:

FIG. 1 is a combined perspective view of an electronic device according to some embodiments of the present disclosure;

FIG. 2 is an exploded perspective view of an electronic device according to some embodiments of the present disclosure;

FIG. 3 is a block diagram of an electronic device according to some embodiments of the present disclosure;

FIG. 4 is a plan view of a display panel according to some embodiments of the present disclosure;

FIG. 5 is an equivalent circuit diagram of a pixel according to some embodiments of the present disclosure;

FIG. 6 is a cross-sectional view of a display panel according to some embodiments of the present disclosure;

FIG. 7 is an enlarged plan view of a portion of an active area according to some embodiments of the present disclosure;

FIGS. 8A and 8B are respective schematic diagrams of signals according to some embodiments of the present disclosure;

FIG. 9 is a cross-sectional view of a display panel according to some embodiments of the present disclosure;

FIG. 10 is a cross-sectional view of a display panel according to some embodiments of the present disclosure;

FIG. 11 is a cross-sectional view of a display panel according to some embodiments of the present disclosure;

FIGS. 12A and 12B are respective schematic diagrams of signals according to some embodiments of the present disclosure; and

FIG. 13 is a cross-sectional view of a display panel according to some embodiments of the present disclosure.

### DETAILED DESCRIPTION

Aspects of some embodiments of the present invention may be variously modified and realized in various forms, and thus aspects of some embodiments will be illustrated in the drawings and described in more detail hereinafter. However, it will be understood that embodiments according to the present invention are not intended to be limited to the specific forms set forth herein, and all changes, equivalents, and substitutions included in the technical scope and spirit of the present invention are included.

It will be understood that when an element or layer is referred to as being “on” or, “connected to”, or “coupled to” another element or layer, it means that the element may be directly located on/connected to/coupled to the other element, or a third element may be located therebetween.

Meanwhile, “being directly located” may mean that there is not an additional layer, film, region, plate or the like between a part of a layer, film, region, plate or the like and another part. For example, “being directly located” may mean that the presence or absence of two layers or two members is performed without using an additional member such as an adhesive member therebetween.

Like reference numerals in the drawings refer to like elements. In addition, in the drawings, the thickness and the ratio and the dimension of the element are exaggerated for effective description of the technical contents.

The term “and/or” includes all combinations of one or more of which associated configurations may define.

Terms such as first, second, and the like may be used to describe various elements, but these elements should not be limited by the terms. The terms are only used to distinguish one element from another. For example, a first element could be termed a second element, and, similarly, a second element could be termed a first element, without departing from the scope of example embodiments of the disclosure. The singular expressions include plural expressions unless the context clearly dictates otherwise.

In addition, terms such as “below,” “lower,” “above,” “upper,” and the like are used to describe the relationship of the configurations shown in the drawings. The terms are used as a relative concept and are described with reference to the direction indicated in the drawings. In the present specification, the term “located on” may refer to not only an upper part of any member but also a lower part thereof.

It should be understood that the terms “comprise” or “have” are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used herein have the same meaning as commonly understood by one of ordinary skill in the art to which the disclosure pertains. In addition, it will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Hereinafter, aspects of some embodiments of the present disclosure will be described in more detail with reference to the accompanying drawings.

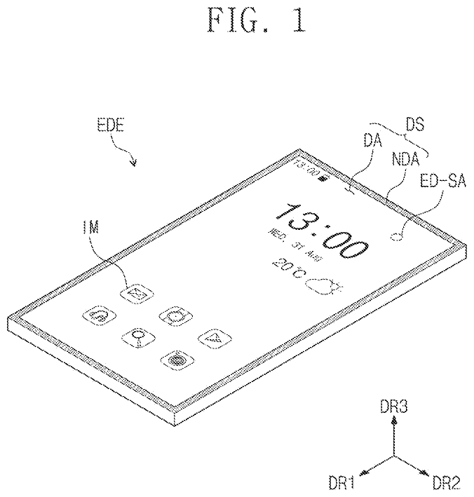

FIG. 1 is a combined perspective view of an electronic device EDE according to some embodiments of the present disclosure.

Referring to FIG. 1, the electronic device EDE according to some embodiments of the present disclosure may include a display surface DS defined by (or parallel to a plane defined by) a first direction DR1 and a second direction DR2 crossing the first direction DR1. The electronic device EDE may display images IM through at display surface DS.

The display surface DS may include a display area DA and a non-display area NDA around the display area DA. The display area DA may display an image IM, and the non-display area NDA may not display the image IM. The non-display area NDA may surround the display area DA. However, the embodiments of the present disclosure are not limited thereto, and the shapes of the display area DA and the non-display area NDA may be modified. According to some embodiments of the present disclosure, the non-display area NDA may be omitted.

Hereinafter, a direction substantially vertically crossing (e.g., perpendicular or normal with respect to) the plane defined by the first and second directions DR1 and DR2 is defined as a third direction DR3. In addition, in the present specification, an expression “in a plan view” may refer to a state of viewing toward the display surface DS from the third direction DR3.

A sensing area ED-SA may be defined in the display area DA of the electronic device EDE. In FIG. 1, one example sensing area ED-SA is shown, but the number of the sensing areas ED-SA is not limited thereto. The sensing area ED-SA may be surrounded by the display area DA. Accordingly, the electronic device EDE may not display an image through the sensing area ED-SA.

An electronic module may be located in an area overlapping the sensing area ED-SA. The electronic module may receive an external input delivered through the sensing area ED-SA, or provide an output through the sensing area ED-SA. For example, the electronic module may be a sensor configured to measure a distance, such as a camera module or a proximity sensor, a sensor configured to recognize a part (e.g., a fingerprint, an iris, or the face) of the user, or a small lamp configured to output light, but is not particularly limited thereto. Hereinafter, a case where an example electronic module overlapping the sensing area ED-DA is a camera module will be described.

In FIG. 1, an example bar-type (or non-bendable, planar) electronic device EDE is shown, but the embodiments of the present disclosure are not limited thereto. For example, embodiments of the present disclosure may also be applied to a flexible electronic device, such as a foldable electronic device, a rollable electronic device, or a slidable electronic device.

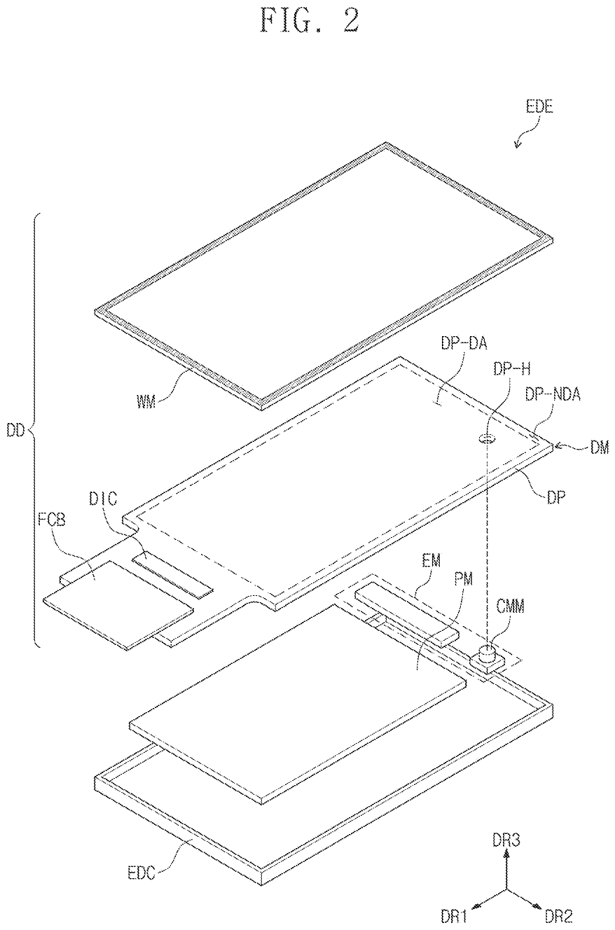

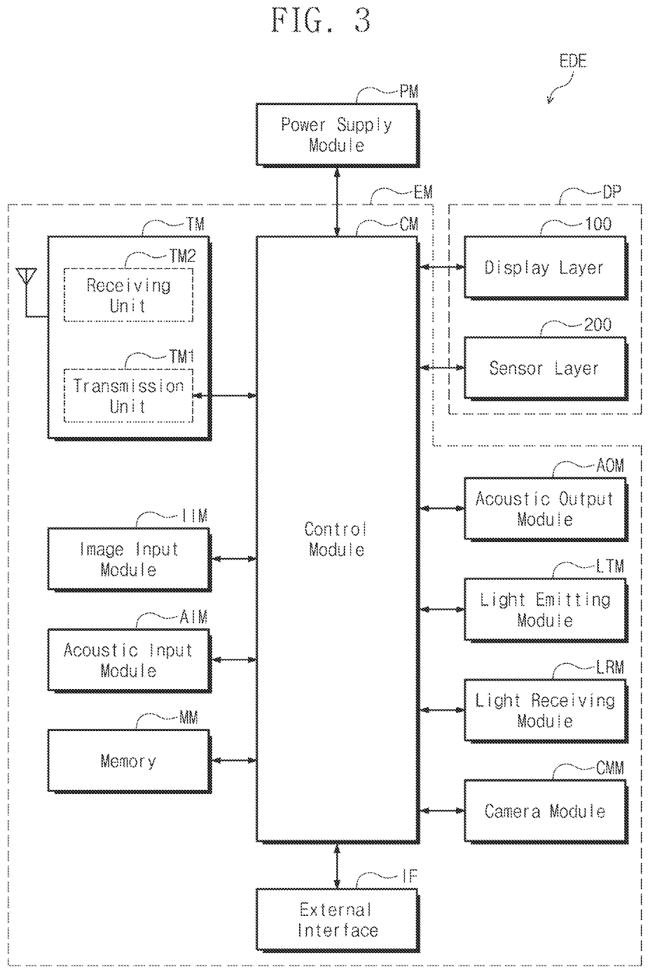

FIG. 2 is an exploded perspective view of the electronic device EDE according to some embodiments of the present disclosure. FIG. 3 is a block diagram of the display device EDE according to some embodiments of the present disclosure.

Referring to FIGS. 2 and 3, the electronic device EDE may include a display device DD, an electronic module EM, a power supply module PM, and a housing EDC.

The display device DD includes a window module WM and a display module DM. The window module WM may provide the front surface of the electronic device EDE. The display module DM may include at least a display panel DP. The display module DM may generate images and detect an external input.

In FIG. 2, the display module DM is shown as being the same as the display panel DP, but substantially the display module DM may be a laminated structure in which a plurality of components including the display panel DP are laminated.

The display panel DP may include a display area DP-DA and a non-display area DP-NDA respectively corresponding to the display area DA (see FIG. 1A) and the non-display area NDA (see FIG. 1A). In the specification, “an area/part corresponds to an area/part” means overlapping, and the overlapping is not limited to having the same area.

A hole DP-H may be defined in the display panel DP. For example, the hole DP-H may be defined by removing a portion of the display panel DP. The display area DP-DA of the display panel DP may surround the hole DP-H.

The hole DP-H may overlap or correspond to the sensing area ED-SA (see FIG. 1A) of the electronic device EDE. According to some embodiments, the hole DP-H is shown in a circular shape, but the hole DP-H may have various shapes including a polygon, an ellipse, a figure having at least one curve side, or an atypical shape, and is not limited to any one embodiment.

According to some embodiments of the present disclosure, the hole DP-H may be omitted. In other words, the sensing area ED-SA (see FIG. 1) may be a portion of the display area DP-DA. Accordingly, the electronic device EDE (see FIG. 1) may display an image through the sensing area ED-SA. In this case, the transmittance of an area overlapping a camera model CMM may be higher than that of the surrounding area.

The display panel DP may include a display layer 100 and a sensor layer 200.

The display layer 100 may be a component configured to substantially generate an image. The display layer 100 may be an emissive display layer, for example, an organic light emitting display layer, an inorganic light emitting display layer, an organic-inorganic light emitting display layer, a quantum dot display layer, a micro LED display layer, or a nano LED display layer.

The sensor layer 200 may sense an external input applied from the outside. The external input may be a user input. The user input includes various types of external inputs including a part of the user's body, light, heat, a pen, pressure or the like.

The display module DM may include a driving chip DIC located on the non-display area DP-NDA. The display module DM may further include a flexible circuit film FCB coupled to the non-display area DP-NDA.

The driving chip DIC may include driving elements, for example, a data driving circuit for driving pixels of the display panel DP. FIG. 2 illustrates a structure in which the driving chip DIC is mounted on the display panel DP, but the embodiments of the present disclosure are not limited thereto. For example, the driving chip DIC may be mounted on the flexible circuit film FCB.

The power supply module PM may supply power necessary for the entire operation of the electronic device EDE. The power supply module PM may include a typical battery module.

The electronic module EM may include various functional modules for operating the electronic device EDE. The electronic module EM may be directly mounted on a mother board electrically connected to the display panel DP, or be mounted on a separate board to be electrically connected to the mother board through a connector.

The electronic module EM may include a control module CM, a wireless transmission module TM, an image input module IIM, an acoustic input module ATM, a memory MM, an external interface IF, an acoustic output module AOM, a light emitting module LTM, a light reception module LRN, the camera module CMM or the like.

The control module CM may control the entire operation of the electronic device EDE. The control module CM may be a microprocessor. For example, the control module CM may activate or deactivate the display panel DP. The control module CM may control the other modules such as the image input module IIM or the acoustic input module AIM on the basis of a touch signal received from the display panel DP.

The wireless communication module TM may communicate with an external electronic device over a first network (e.g., a short-range communication network such as Bluetooth, WiFi direct, or infrared data association (IrDA)) or a second network (e.g., a long-range network, such as a cellular network, the Internet, or a computer network (e.g., LAN or WAN)). Communication modules included in the wireless communication module TM may be integrated into one component (e.g., a single chip), or be implemented with a plurality of separate components (e.g., a plurality of chips). The wireless communication module TM may transmit/receive a voice signal using a general communication line. The wireless communication module TM may include a transmission unit TM1 configured to modulate a signal to be transmitted and transmit the modulated signal, and a receiving unit TM2 configured to demodulate a received signal.

The image input module IIM may process an image signal to convert the processed image signal into image data displayable on the display module DP. The acoustic input module AIM may receive an external acoustic signal through a microphone in a recording mode, a voice recognition mode or the like to convert the acoustic signal to electrical voice data.

The external interface IF may include a connector physically connecting the electronic device EDE and the external electronic device. For example, the external interface IF may serve as an interface connected to an external charger, a wired/wireless data port, or a socket for a card (e.g., a memory card, an SIM/UIM card), etc.

The acoustic output module AOM may convert acoustic data received from the wireless communication module TM or stored in the memory MM, and outputs the converted result to the outside.

The light emitting module LTM may generate to output light. The light emitting module LTM may output infrared light. The light emitting module LTM may include an LED element. The light receiving module LRM may sense infrared light. The light receiving module LRM may be activated when infrared light of a prescribed level or higher is sensed. The light receiving module LRM may include a CMOS sensor. After the infrared light generated in the light emitting module LTM is output, the infrared light is reflected by an external object (e.g., a finger or the face of the user), and the reflected infrared light is incident to the light receiving module LRM.

The camera module CMM may capture a static image or a moving image. The camera module CMM may be provided in plurality. Among them, some camera modules CMM may overlap the hole DP-H. An external input (e.g., light) may be provided to the camera module CMM through the hole DP-H. For example, the camera module CMM may receive natural light through the hole DP-H to capture an external image.

The housing EDC may accommodate the display module DM, the electronic module EM, and the power supply module PM. The housing EDC may protect the components such as the display module EM, the electronic module EM, the power supply module and the like that are accommodated in the housing EDC. The housings EDC may be combined to the window module WM.

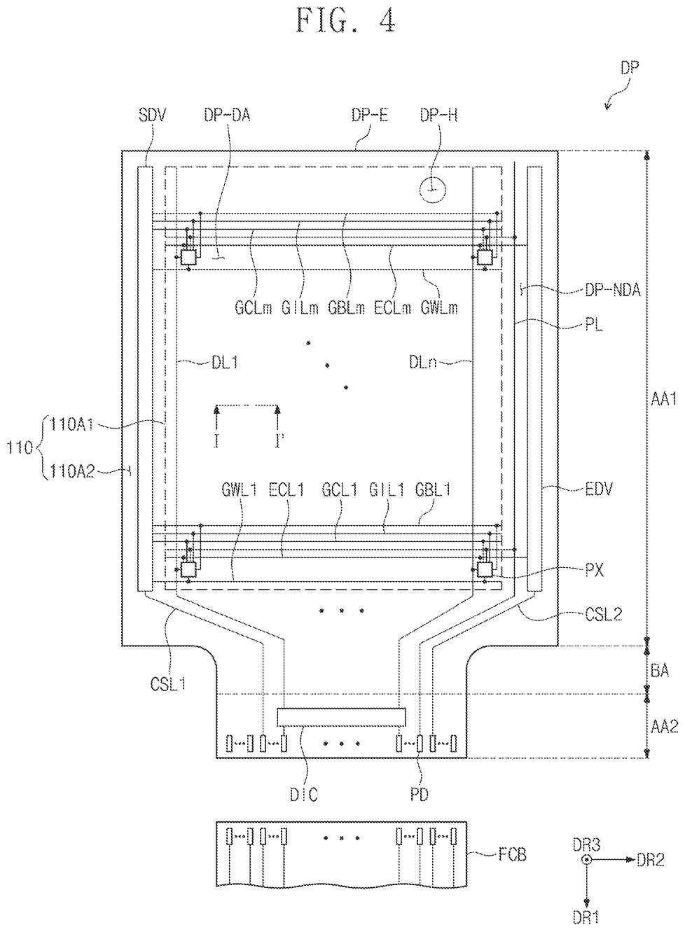

FIG. 4 is a plan view of the display panel DP according to some embodiments of the present disclosure.

With reference to FIG. 4, the display panel DP may include a base layer 110, pixels PX, a scan driving unit SDV, a data driving unit, and a light emission driving unit EDV.

The display area DP-DA and the non-display area DP-NDA around the display area DP-DA may be defined in the display panel DP. The display area DP-DA and the non-display area DP-NDA may be divided by the presence or absence of the plurality of pixels PX. The pixels may be located in the display area DP-DA. The scan driving unit SDV, the data driving unit, and the light emission driving unit EDV may be located in the non-display area DP-NDA. The data driving unit EDV may be a partial circuit provided in the driving chip DIC.

A first area 110A1 and a second area 110A2 may be defined in the base layer 110. The first area 110A1 in the base layer 110 may overlap the display area DP-DA, and the second area 11-A2 may overlap the non-display area DP-NDA. In other words, the first area 110A1 in the base layer 110 may be a base surface on which components located in the display area DA are provided, and the second area 110A2 may be a base surface on which components located in the non-display area DP-NDA are provided.

The display panel DP may include a first panel area AA1, a bending area BA, and a second panel area AA2 defined along the first direction DR1. The second panel area AA2 and the bending area BA may be partial areas of the non-display area DP-NDA. The bending area BA is located between the first panel area AA1 and the second panel area AA2.

The first panel area AA1 corresponds to the display surface DS of FIG. 1. The width, parallel to the second direction DR2, of the bending area BA and the width (or the length) of the second panel area AA2 may be smaller than the width (or the length), parallel to the second direction DR2, of the first panel area AA1. An area with a shorter length in a direction of a bending axis may be bent more easily.

The display panel DP may include the pixels PX, initialization scan lines GIL1 to GILm, compensation scan lines GCL1 to GCLm), write scan lines GWL1 to GWLm, black scan lines GBL1 to GBLm, light emission control lines ECL1 to ECLm, data lines DL1 to DLn, first and second control lines CSL1 and CSL2, a driving voltage line PL, and a plurality of pads PD. Here, m and n may be natural numbers of at least 2.

The pixels PX may be connected to the initialization scan lines GIL1 to GILm, the compensation scan lines GCL1 to GCLm, the write scan lines GWL1 to GWLm, the black scan lines GBL1 to GBLm, the light emission control lines ECL1 to ECLm, and the data lines DL1 to DLn.

The initialization scan lines GIL1 to GILm, the compensation scan lines GCL1 to GCLm, the write scan lines GWL1 to GWLm, and the black scan lines GBL1 to GBLm may extend in the second direction DR2 to be electrically connected to the scan driving unit SDV. The data lines DL1 to DLn may extend in the first direction DR1 to be electrically connected to the driving chip DIC via the bending area BA. The light emission control lines ECL1 to ECLm may extend in the second direction DR2 to be electrically connected to the light emission driving unit EDV.

The driving voltage line PL may include a portion extending in the first direction DR1 and a portion extending in the second direction DR2. The portion extending in the first direction DR1 and the portion extending in the second direction DR2 may be located on different layers. A portion, extending in the first direction DR1, of the driving voltage line PL may extend to the second panel area AA2 via the bending area BA. The driving voltage line PL may provide a driving voltage to the pixels PX.

The first control line CSL1 may be connected to the scan driving unit SDV, and extend towards the lower end of the second panel area AA2 via the bending area BA. The second control line CSL2 may be connected to the emission driving unit EDV and extend towards the lower end of the second panel area AA2 via the bending area BA.

In a plan view, the pads PD may be located adjacent to the lower end of the second area AA2. The driving chip DIC, the driving voltage line PL, the first control line CSL1, and the second control line CSL2 may be electrically connected to the pads PD. The flexible circuit film FCB may be electrically connected to the pads PD through an anisotropic conductive adhesive layer.

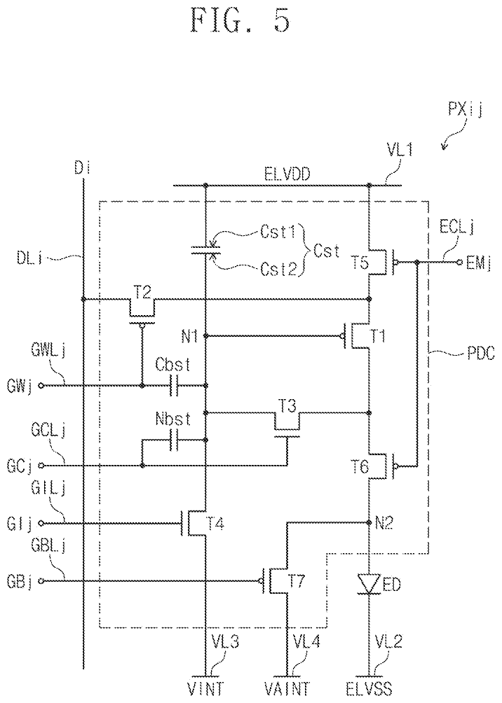

FIG. 5 is an equivalent circuit diagram of a pixel PXij according to some embodiments of the present disclosure.

FIG. 5 shows an example equivalent circuit diagram of one pixel PXij of the plurality of pixels PX (see FIG. 3). Because the plurality of pixels PX have the same circuit structure, a description about the circuit structure of the pixel PXij may be applied to the remaining pixels PX.

Referring to FIGS. 4 and 5, the pixel PXij may be connected to an i-th data line DLi among the data lines DL1 to DLn, a j-th initialization scan line GILj among the initialization scan lines GIL1 to GILm, a j-th compensation scan line GCLj among the compensation scan lines GCL1 to GCLm, a j-th write scan line GWLj among the write scan lines GWL1 to GWLm, a j-th black scan line GBLj among the black scan lines GBL1 to GBLm, a j-th light emission control line ECLj among the light emission control lines ECL1 to ECLm, the first and second driving voltage lines VL1 and VL2, and the first and second initialization voltage lines VL3 and VL4. Here, i is an integer of 1 to n, and j is an integer of 1 to m.

The pixel PXij may include a light emitting element ED and a pixel circuit PDC. The light emitting element ED may include a light emitting diode. According to some embodiments of the present disclosure, the light emitting element ED may be an organic light emitting diode including an organic light emitting layer, but embodiments according to the present disclosure are not limited thereto. The pixel circuit PDC may control an amount of a current flowing through the light emitting element ED in correspondence to a data signal Di. The light emitting element ED may emit light with a prescribed luminance in correspondence to the current amount provided from the pixel circuit PDC.

The pixel circuit PDC may include first to seventh transistors T1, T2, T3, T4, T5, T6, and T7, and first to third capacitors Cst, Cbst, and Nbst. The configuration of the pixel circuit PDC according to some embodiments of the present disclosure is not limited to the embodiments shown in FIG. 5. The pixel circuit PDC shown in FIG. 5 is merely an example, and the configuration of the pixel circuit PDC may be modified and implemented. For example, among the first to third capacitors Cst, Cbst, and Nbst, the second and third capacitors Cbst and Nbst may be omitted.

At least one of the first to seventh transistors T1, T2, T3, T4, T5, T6, or T7 may be a transistor having a low-temperature polycrystalline silicon (LTPS) semiconductor layer. At least one of the first to seventh transistors T1 to T7 may be an oxide transistor. For example, the third and fourth transistors T3 and T4 may be oxide transistors, and the first, second, fifth, sixth, and seventh transistors T1, T2, T5, T6, and T7 may be LTPS transistors.

For example, the first transistor T1, which directly influences the brightness of the display device ED, may be configured to include a semiconductor layer composed of highly reliable polycrystalline silicon, resulting in implementation of a display device with high resolution. Meanwhile, the oxide semiconductor has a high carrier mobility and a low leakage current, and thus a voltage drop is not large despite of a long driving time. In other words, a change in color of an image according to the voltage drop is not large even during low frequency driving, and thus low frequency driving is possible. In this way, the oxide semiconductor may be advantageous in a small leak current, and thus at least one of the third transistor T3 connected to a gate electrode of the first transistor T1 and the fourth transistor T4 may employ the oxide semiconductor to prevent or reduce leakage current flowing to the gate electrode, and reduce power consumption.

Some of the first to seventh transistors T1 to T7 may be P-type transistors, and the others may be N-type transistors. For example, the first, second, fifth, sixth, and seventh transistors T1, T2, T5, T6, and T7 may be P-type transistors, and the third and fourth transistors T3 and T4 may be N-type transistors.

The configuration of the pixel circuit PDC according to some embodiments of the present disclosure is not limited to the embodiments shown in FIG. 5. The pixel circuit PDC shown in FIG. 5 is merely an example and the configuration of the pixel circuit PDC may be modified and implemented. For example, all the first to seventh transistors T1 to T7 may be P-type transistors, or N-type transistors. Alternatively, the first, second, fifth, and sixth transistors T1, T2, T5, and T6 may be P-type transistors, and the third, fourth, and the seventh transistors T3, T4, and T7 may be N-type transistors.

The j-th initialization scan line GILj, the j-th compensation scan line GCLj, the j-th write scan line GWLj, the j-th black scan line GBLj, and the j-th light emission control line ECLj may respectively deliver, to the pixel PXij, a j-th initialization scan signal Glj, a j-th compensation scan signal GCj, a j-th write scan signal GWj, a j-th black scan signal GBj, and a j-th light emission control signal EMj. The i-th data line DLi may deliver an i-th data signal Di to the pixel PXij. The i-th data signal Di may have a voltage level corresponding to the image signal input to the display device DD (see FIG. 2).

The first and second driving voltage lines VL1 and VL2 may respectively deliver a first driving voltage ELVDD and a second driving voltage ELVSS to the pixel PXij. In addition, the first and second initialization voltage lines VL3 and VL4 may respectively deliver a first initialization voltage VINT and a second initialization voltage VANIT to the pixel PXij.

The first transistor T1 may be connected between the first driving voltage line VL1 receiving the first driving voltage, and the light emitting element ED. The first transistor T1 may include a first electrode connected to the first driving voltage line VL1 via the fifth transistor T5, a second electrode electrically connected to a pixel electrode (or referred to as an anode) of the light emitting diode ED via the sixth transistor T6, and a third electrode (e.g., a gate electrode) connected to one end of the first capacitor Cst. The first transistor T1 may receive the i-th data signal Di delivered through the i-th data line DLi according to a switching operation of the second transistor T2, and provides a driving current Id to the light emitting diode ED.

The second transistor T2 may be connected between the data line DLi and the first electrode of the first transistor T1. The second transistor T2 may include a first electrode connected to the data line DLi, a second electrode connected to the first electrode of the first transistor T1, and a third electrode (e.g., a gate electrode) connected to the j-th write scan line GWLj. The second transistor T2 may be turned on in response to the j-th write scan signal GWj delivered through the j-th write scan line GWLj to deliver the i-th data signal Di, delivered from the i-th data line DLi, to the first electrode of the first transistor T1. One end of the second capacitor Cbst may be connected to the third electrode of the second transistor T2, and the other end may be connected to the first node N1.

The third transistor T3 is connected between the second electrode of the first transistor T1 and the first node N1. The third transistor T3 may include a first electrode connected to the third electrode of the first transistor T1, a second electrode connected to the second electrode of the first transistor T1, and a third electrode (e.g., a gate electrode) connected to the j-th compensation scan line GCLj. The third transistor T3 may be turned on in response to the j-th compensation scan signal GCLj delivered through the j-th compensation scan line GCLj to connect the third electrode and the second electrode of the first transistor T1 to diode-connect the first transistor T1. One end of the third capacitor Nbst may be connected to the third electrode of the third transistor T3, and the other end may be connected to the first node N1.

The fourth transistor T4 is connected between the first node N1 and the first initialization voltage line VL3 to which the first initialization voltage VINT is applied. The fourth transistor T4 may include a first electrode connected to the first initialization line VL3 to which the first initialization voltage VINT is delivered, a second electrode connected to the first node N1, and a third electrode (e.g., a gate electrode) connected to the j-th initialization scan line GILj. The fourth transistor T4 may be turned on in response to the j-th initialization scan signal Glj delivered through the j-th initialization scan line GILj. The turned on fourth transistor T4 delivers the first initialization voltage VINT to the first node N1 to initialize a potential of the third electrode of the first transistor T1 (i.e., a potential of the first node N1).

The fifth transistor T5 may include a first electrode connected to the first driving voltage line VL1, a second electrode connected to the first electrode of the first transistor T1, and a third electrode (e.g., a gate electrode) connected to the j-th light emission control line ECLj. The sixth transistor T6 may include a first electrode connected to the second electrode of the first transistor T1, a second electrode connected to a pixel electrode of the light emitting element ED, and a third electrode (e.g., a gate electrode) connected to the j-th light emission control line ECLj.

The fifth and sixth transistors T5 and T6 may be substantially simultaneously turned on in response to the j-th light emission control signal EMj delivered through the j-th light emission control line ELj. The first driving voltage ELVDD applied through the turned-on fifth transistor T5 may be compensated through the diode-connected first transistor T1 and then delivered to the light emitting element ED.

The seventh transistor T7 may include a first electrode connected to the second initialization line VL4 to which the second initialization voltage VAINT is delivered, a second electrode connected to the second electrode of the sixth transistor T6, and a third electrode (e.g., a gate electrode) connected to the j-th black scan line GBLj. The second initialization voltage VAINT may have a lower level than the first initialization voltage VINT.

One end of the first capacitor Cst is connected to the third electrode of the third transistor T1, and the other end is connected to the first driving voltage line VL1. A cathode of the light emitting diode ED may be connected to the second driving voltage line VL2 delivering the second driving voltage ELVSS. The second driving voltage ELVSS may have a lower level than the first driving voltage ELVDD.

Although various components are illustrated and described with respect to FIG. 5, embodiments according to the present disclosure are not limited thereto. For example, according to some embodiments, the pixel PXij may include additional components or fewer components without departing from the spirit and scope of embodiments according to the present disclosure.

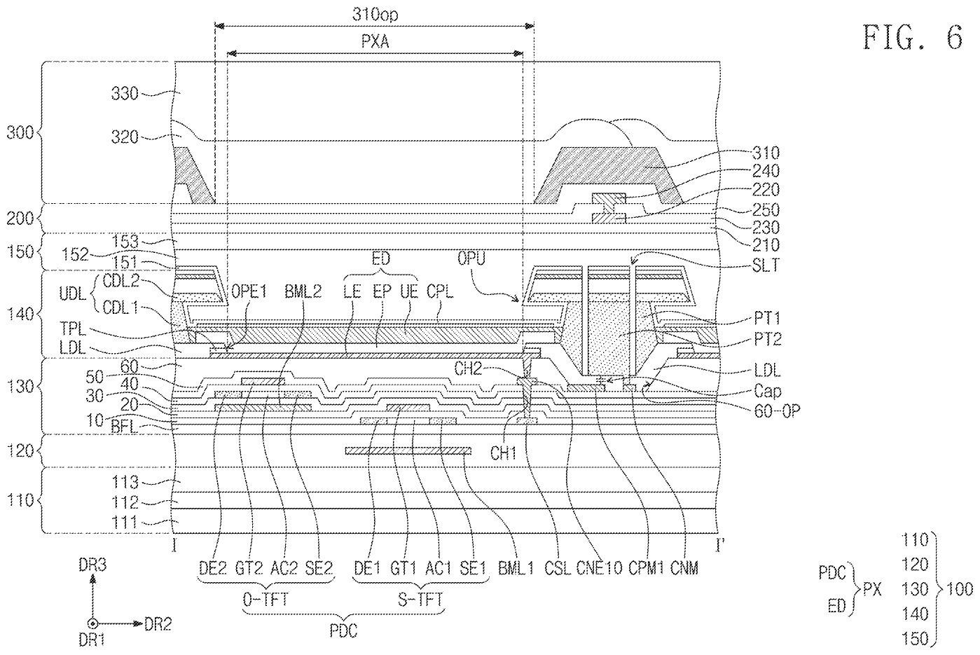

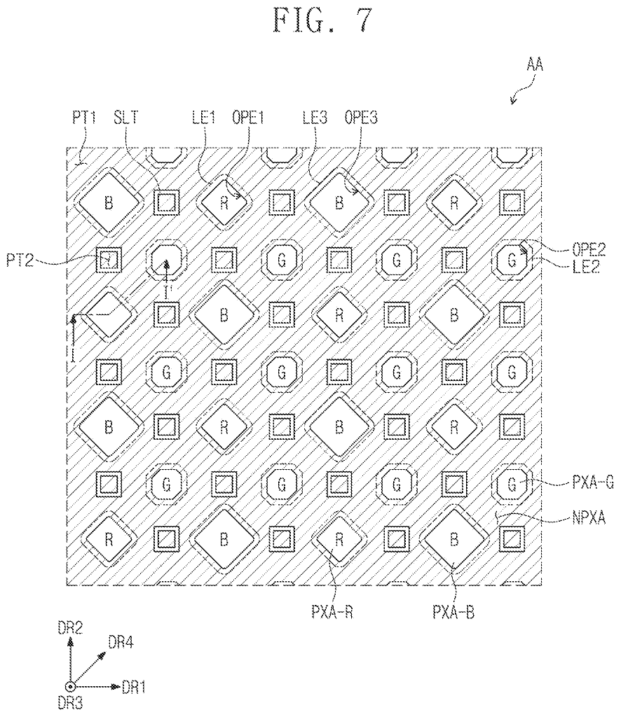

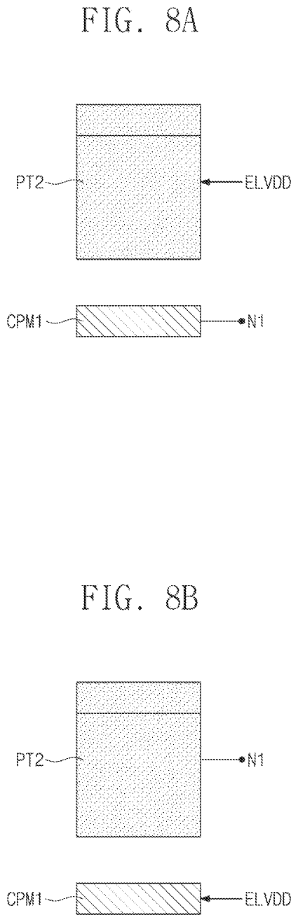

FIG. 6 is a cross-sectional view of the display panel DP according to some embodiments of the present disclosure. FIG. 7 is an enlarged plan view of a portion of the active area AA according to some embodiments of the present disclosure. FIGS. 8A and 8B are respective schematic diagrams of signals according to some embodiments of the present disclosure.

FIG. 6 may be a cross-sectional view taken along a line I-I′ of FIG. 4. In addition, FIG. 6 may be an example cross-sectional view taken along a line I-I′ of FIG. 7.

Referring to FIG. 6, the display panel DP may include a display layer 100, a sensor layer 200, and an anti-reflection layer 300. The display layer 100 may include a base layer 110, a barrier layer 120, a circuit layer 130, a light emitting element layer 140, and an encapsulation layer 150.

The base layer 110 may first to third sub-base layers 111, 112, 113. Each of the first sub-base layer 111 and the third sub-base layer 113 may include at least one among a polyimide-based resin, an acrylate-based resin, a methacrylate-based resin, a polyisoprene-based resin, a vinyl-based resin, an epoxy-based resin, an urethane-based resin, a cellulose-based resin, a siloxane-based resin, a polyamide-based resin, or a perylene-based resin. Further, in the present disclosure, “˜˜”-based resin means including a functional group of “˜˜”. For example, each of the first sub-base layer 111 and the third sub-base layer 113 may include polyimide.

The second sub-base layer 112 may have a single layer or multi-layer structure. For example, the second sub-base layer 112 may include an inorganic material, and include at least one among silicon oxide, silicon nitride, silicon oxynitride, and an amorphous silicon. For example, the second sub-base layer 112 may include silicon oxynitride and silicon oxide laminated thereon.

The barrier layer 120 may be located on the base layer 110. The barrier layer 120 may have a single layer or multi-layer structure. The barrier layer 120 may include at least one among silicon oxide, silicon nitride, silicon oxynitride, or an amorphous silicon.

The barrier layer 120 may further include a first lower light shielding layer BML1. For example, when the barrier layer 120 has a multi-layer structure, the first lower light shielding layer BML1 may be located between layers constituting the barrier layer 120. However, the embodiments of the present disclosure are not limited thereto, and the first lower light shielding layer BML1 may be located between the base layer 110 and the barrier layer 120, or on the barrier layer 120. According to some embodiments, the first lower light shielding layer BML1 may be omitted. The first lower light shielding layer BML1 may be referred to as a first lower layer, a first lower metal layer, a first lower electrode layer, a first lower blocking layer, a first light shielding layer, a first metal layer, a first blocking layer, or a first overlapping layer.

The buffer layer BFL may be located on the barrier layer 120. The buffer layer BFL may prevent or reduce a phenomenon in which metal atoms, impurities, or contaminants diffuse to a first semiconductor pattern. In addition, the buffer layer BFL may allow the first semiconductor pattern to be provided uniformly by adjusting a thermal speed during a crystallization process.

The buffer layer BFL may include a plurality of inorganic layers. For example, the buffer layer BFL may include a first sub-buffer layer and a second sub-buffer layer located on the first sub-buffer layer and including silicon oxide.

The light emitting element layer 140 may be located on the circuit layer 130. The pixel PX may include the pixel circuit PDC and the light emitting element ED electrically connected to the pixel circuit PDC. The pixel circuit PDC may be included in the circuit layer 130, and the light emitting element ED may included in the light emitting element layer 140.

FIG. 6 illustrates an example silicon thin-film transistor S-TFT and an example oxide thin-film transistor O-TFT of the pixel circuit PDC are shown. The silicon thin-film transistor S-TFT may be one among the first, second, fifth, sixth, or seventh transistors T1, T2, T5, T6, or T7, and the oxide thin-film transistor O-TFT may be one of the third or fourth transistors T3 or T4.

The first semiconductor pattern may be located on the buffer layer BFL. The first semiconductor pattern may include a silicon semiconductor. For example, the silicon semiconductor may include an amorphous silicon, polycrystalline silicon, or the like. For example, the first semiconductor pattern may include low temperature polysilicon.

FIG. 6 merely illustrates a portion of the first semiconductor pattern located on the buffer layer BFL, and the other first semiconductor pattern may be further located in another area. The first semiconductor pattern may be arranged across the pixels in a specific rule. The first semiconductor pattern may have different electrical properties according to whether it is doped or not. The first semiconductor pattern may include a first area having a high conductivity and a second area having a low conductivity. The first area may be doped with an N-type dopant or a P-type dopant. A P-type transistor includes a doped region doped with a P-type dopant, and an N-type transistor includes a doped area doped with an N-type dopant. The second area may be a non-doped area, or be doped at a lower concentration in comparison to the first area.

The first area may have a greater conductivity than the second area, and substantially operate as an electrode or a signal line. The second area may substantially correspond to an active area (or a channel) of the transistor. In other words, a portion of the semiconductor pattern may be the active area of the transistor, another portion may be a source or a drain of the transistor, and another portion may be a connection electrode or a signal connection line.

A source area SE1, an active area AC1, and a drain area DE1 of the silicon thin transistor S-TFT may be provided from the first semiconductor pattern. The source area SE1 and the drain area DE1 may extend in opposite directions from each other from the active area AC1 on a cross section.

FIG. 6 illustrates a portion of the signal connection line CSL provided from the first semiconductor pattern. The connection signal line CSL may be connected to the second electrode of the sixth transistor T6 (see FIG. 5) in a plan view.

The circuit layer 130 may include a plurality of inorganic layers and a plurality of organic layers. According to some embodiments, first to sixth insulation layers 10, 20, 30, 40, and 50 sequentially laminated on the buffer layer BFL may be inorganic layers, and a sixth insulation layer may be an organic layer.

The first insulation layer 10 may be located on the buffer layer BFL. The first insulation layer 10 may cover the first semiconductor pattern. The first insulation layer 10 may include an inorganic material and/or organic material, and have a single layer or multilayer structure. The first insulation layer 10 may include at least one among aluminum oxide, titanium oxide, silicon oxide, silicon nitride, silicon oxynitride, zirconium oxide, or halfnium oxide. According to some embodiments, the first insulation layer 10 may be a single silicon oxide layer. Not only the first insulation layer 10, but also an insulation layer of the circuit layer 130 may have a single layer or multilayer structure.

A gate electrode GT1 of the silicon thin-film transistor S-TFT may be located on the first insulation layer 10. The gate electrode GT1 may be a portion of the metal pattern. The gate electrode GT1 may overlap the active area AC1. The gate electrode GT1 may function as a mask in a process for doping the first semiconductor pattern. The gate electrode GT1 may include titanium, silver, an alloy containing silver, molybdenum, an alloy containing molybdenum, aluminum, an alloy containing aluminum, aluminum nitride, tungsten, tungsten nitride, copper, indium tin oxide, indium zinc oxide or the like, but is not particularly limited thereto.

The second insulation layer 20 may be located on the first insulation layer 10 and cover the gate electrode GT1. The second insulation layer 20 may be an inorganic material, and have a single layer or multilayer structure. The second insulation layer 20 may include at least one among silicon oxide, silicon nitride, or silicon oxynitride. According to some embodiments, the second insulation layer 20 may have a single layer structure including a silicon nitride layer.

A third insulation layer 30 may be located on the second insulation layer 20. The third insulation layer 30 may be an inorganic layer, and have a single layer or multilayer structure. For example, the third insulation layer 30 may have a multilayer structure including a silicon oxide layer and a silicon nitride layer.

A second semiconductor pattern may be located on the third insulation layer. The second semiconductor pattern may include silicon oxide semiconductor. The silicon oxide semiconductor may include a plurality of areas divided according to whether a metal oxide is reduced. An area (hereinafter, a reduction area) in which the metal oxide is reduced has a high conductivity in comparison to an area (hereinafter, a non-reduction area) in which the metal oxide is not reduced. The reduction area may substantially serve as a source/drain or a signal line of the transistor. The non-reduction area substantially corresponds to the active area (or a semiconductor area, a channel) of the transistor. In other words, a portion of the second semiconductor pattern may be the active area of the transistor, another portion may be a source/drain area of the transistor, and still another portion may be a signal delivery area.

A source area SE2, an active area AC2, and a drain area DE2 of the oxide thin-film transistor O-TFT may be provided from the second semiconductor pattern. The source area SE2 and the drain area DE2 may extend in opposite directions from each other from the active area AC2 on a cross section.

A fourth insulation layer 40 may be located on the third insulation layer 30. The fourth insulation layer 40 may cover the second semiconductor pattern. The fourth insulation layer 40 may be an inorganic layer, and have a single layer or multilayer structure. The fourth insulation layer 40 may include at least one among aluminum oxide, titanium oxide, silicon oxide, silicon nitride, silicon oxynitride, zirconium oxide, or halfnium oxide. According to some embodiments, the fourth insulation layer 40 may have a single layer structure including silicon oxide.

A gate electrode GT2 of the oxide thin-film transistor O-TFT may be located on the fourth insulation layer 40. The gate electrode GT2 may be a portion of the metal pattern. The gate electrode GT2 may overlap the active area AC2. The gate electrode GT2 may function as a mask in a process for reducing the second semiconductor pattern.

A second light shielding layer BML2 may be located under the oxide thin-film transistor O-TFT. The second light shielding layer BML2 may be located between the second insulation layer 20 and the third insulation layer 30.

The fifth insulation layer 50 may be located on the fourth insulation layer 40 and cover the gate electrode GT2. The fifth insulation layer 50 may be an inorganic and/or an organic layer, and have a single layer or multilayer structure. For example, the fifth insulation layer 50 may have a multilayer structure including a silicon oxide layer and a silicon nitride layer.

The first connection electrode CNE10 may be located on the fifth insulation layer 50. The first connection electrode CNE10 may be connected to the connection signal line CSL through a first contact hole CH1 penetrating through the first to fifth insulation layers 10, 20, 30, 40 and 50.

A sixth insulation layer 60 may be located on the fifth insulation layer 50. A first electrode LE of the light-emitting element layer 140 may be located on the sixth insulation layer 60. The first electrode LE may be connected to the first connection electrode CNE10 through a second hole CH2 penetrating through the sixth insulation layer 60.

The sixth insulation layer 60 may be an organic layer. For example, the sixth insulation layer and 60 may include a general purpose polymer such as Benzocyclobutene (BCB), polyimide, Hexamethyldisiloxane (HMDSO), Polymethylmethacrylate(PMMA), or Polystyrene(PS), a polymer derivative having a phenol-based group, an acryl-based polymer, an imide-based polymer, an allyl ether-based polymer, an amide-based polymer, a fluorine-based polymer, a p-xylene-based polymer, a vinylalcohol-based polymer, or a blend thereof.

The light emitting element layer 140 may be located on the circuit layer 130. The light emitting element layer 140 may include the light emitting element ED, a lower pixel definition layer LDL, and an upper pixel definition layer UDL. The lower pixel definition layer LDL may be referred to as a first bank layer, a pixel definition layer, or a first bank insulation layer. The upper pixel definition layer UDL may be referred to as a second bank layer, a conductive bank layer, a wall, or a conductive wall.

The light emitting element ED may include the first electrode LE, a light emitting pattern EP, and a second electrode UE. The light emitting pattern EP may include the light emitting layer and functional layers. For example, the light emitting pattern EP may be a functional layer, and include at least one selected from among an electron injection layer, an electron transport layer, a hole control layer, a hole injection layer, a hole transport layer, and an electron control layer. The functional layers and the second electrode UE may be commonly provided to the pixels PX. The first electrode LE may be referred to as a pixel electrode or an anode, and the second electrode UE may be referred to as a common electrode or a cathode.

The first electrode LE may be located on the sixth insulation layer 60. The first electrode LE may be connected to the first connection electrode CNE10, which is electrically connected to the pixel circuit PDC, through the second contact hole CH2 penetrating through the sixth insulation layer 60.

The first electrode LE may be a (semi-) light transmitting electrode or a reflective electrode. According to some embodiments, the first electrode LE may include the reflective layer composed of silver, magnesium, aluminum, platinum, palladium, gold, nickel, neodymium, iridium, chrome, or a compound thereof, and a transparent or semi-transparent electrode layer provided on the reflective layer. The transparent or semi-transparent electrode layer may include at least one selected from a group consisting of indium tin oxide, indium zinc oxide, indium gallium zinc oxide, zinc oxide or indium oxide, and aluminum-doped zinc oxide. For example, the first electrode LE may include a multilayer structure in which indium tin oxide, silver, and indium tin oxide are sequentially laminated.

The lower pixel definition layer LDL may be located on the sixth insulation layer 60. The lower pixel definition layer LDL may have light absorption property, and have, for example, a block color. The lower pixel definition layer LDL may include a black coloring agent. The black coloring agent may include a black dye or a black pigment. The black coloring agent may include carbon black, a metal such as chromium, or an oxide thereof.

An opening, which exposes a portion of the first electrode LE, may be defined in the lower pixel definition layer LDL, and correspond to the light emitting area PXA. The lower pixel definition layer LDL may cover an edge of the first electrode LE, and the light emitting area PXA may be defined.

In FIG. 6, among first to third light emitting openings OPE1, OPE2, and OPE3 (see FIG. 7), only the first light emitting opening OPE1 is shown. The first to third light emitting openings OPE1, OPE2, OPE3 may correspond to first to third light emitting areas PXA-R, PXA-G, PXA-B. In FIG. 6, the first to third light emitting openings OPE1, OPE2, OPE3 are collectively shown as the light emitting area PXA.

The upper light emitting element layer UDL may be located on the circuit layer 130. An upper opening OPU corresponding to the light emitting area PXA may be defined by the upper pixel definition layer UDL.

The upper pixel definition layer UDL may include a first part PT1 electrically connected to the second electrode UE, and a second part PT2 electrically insulated from the first part PT1. In addition, the second part PT2 may be surrounded by the first part PT1 as shown in FIG. 7. The first part PT1 is a part receiving the second driving voltage ELVSS, and may be referred to a driving voltage delivery unit, or a driving voltage delivery wall. The second part PT2 is an electrode constituting the first capacitor Cst shown in FIG. 5, and may be referred to as an island electrode or a capacitor electrode.

The circuit layer 130 may further include a connection metal CNM electrically connected with the second part PT2. The connection metal CNM may deliver a signal to the second part PT2. The lower pixel definition layer LDL may include an opening to which the second part PT2 may contact the connection metal CNM.

The circuit layer 130 may further include a first cap metal CPM1 located under the second part PT2. In FIG. 6, the first cap metal CPM1 is shown located on the top surface of the fifth insulation layer 50, but is not limited thereto. For example, the first cap metal CPM1 may be located between the fourth insulation layer 40 and the fifth insulation layer 50, or between the third insulation layer 30 and the fourth insulation layer 40.

The first cap metal CPM1 may overlap at least a portion of the second part PT2 in a plan view. Accordingly, the second part PT2 and the first cap metal CPM1 may constitute the first capacitor Cst (see FIG. 5) having cap capacity Cap.

For example, referring to FIGS. 5 and 8A, the second part PT2 may be the first capacitor electrode Cst1 connected to the driving voltage line VL1 to which the driving voltage ELVDD is provided, and the first cap metal CPM1 may be the second capacitor electrode Cst2 connected to the gate electrode of the driving transistor T1 via the first node N1.

On the contrary, referring to FIGS. 5 and 8B, the second part PT2 may be the second capacitor electrode Cst2 connected to the gate electrode of the driving transistor T1 via the first node N1, and the first cap metal CPM1 may be the first capacitor electrode Cst1 connected to the driving voltage line VL1 to which the driving voltage ELVDD is provided.

According to some embodiments of the present disclosure, the upper pixel definition layer UDL may include a conductive material. Accordingly, by means of a portion of the upper pixel definition layer UDL, a capacitor electrode constituting the first capacitor Cst (see FIG. 5) of the pixel circuit PDC (see FIG. 5) may be implemented. Accordingly, the area of a region in which the pixel circuit PDC is located may be reduced.

Meanwhile, an opening may be defined in at least one insulation layer. For example, as shown in FIG. 6, an opening 60-OP may be defined in the sixth insulation layer 60. The lower pixel definition layer LDL may contact the first cap metal CPM1 exposed by the sixth insulation layer 60.

In this case, the distance between the first cap metal CPM1 and the first part PT1 may be greater than that between the first cap metal CPM1 and the second part PT2. The distance between the first cap metal CPM1 and the first part PT1 may mean that the first cap metal CPM1 is the most distant from the first part PT1.

FIG. 7 may be an enlarged view of the active area AA looking down in the third direction DR3 according to some embodiments of the present disclosure. In FIG. 7, the upper pixel definition layer UDL is shown with hatch. In the upper pixel definition layer UDL, upper openings OPU (see FIG. 6), overlapping the first to third openings OPE1, OPE2, OPE3 corresponding to the first to third light emitting areas PXA-R, PXA-G, PXA-B, may be defined.

The upper pixel definition layer UDL may include the second part PT2 located between the first part PT1 and the first to third light emitting areas PXA-R, PXA-G, PXA-B. A slit SLT may be defined in the upper pixel definition layer UDL, and the second part PT2 may be spaced apart from the first part PT1 by the slot SLT. In FIG. 7, the shape of the slit SLT is shown as a rectangle in a plan view, but is not limited thereto. Specifically, the shape of the slit SLT may be a polygon or a ring. For example, as shown in FIG. 7, the slit SLT may have the shape formed by overlapping two rectangles. Alternatively, the slit SLT may have a ring-type shape formed by overlapping two circles.

The second part PT2 may be electrically insulated from the first part PT1 by the slit SLT. The slit SLT may be filled with an organic encapsulation film 152. In addition, as shown in FIG. 7, the first part PT1 is not divided into a plurality of spaced parts, but is formed as an integrated type.

The active area AA may include the first to third light emitting areas PXA-R, PXA-G, PXA-B, and a non-light emitting area NPXA. The non-light emitting area NPXA may correspond to the first part PT1, the second part PT2, and the slit SLT in a plan view.

Meanwhile, the upper pixel definition layer UDL may include a first conductive layer CDL1 located on the circuit layer 130 and a second conductive layer CDL2 located on the first conductive layer CDL1. The second electrode UE may contact at least a portion of a side surface of the conductive layer CDL1. Specifically, the second electrode UE may contact at least the portion of the side surface of the first conductive layer CDL1 of the first part PT1. Accordingly, the second electrode UE may be electrically connected to the first conductive layer CDL1. The first part PT1 may be electrically connected with the second driving voltage line VL2 delivering the second driving voltage ELVSS. The second electrode UE may receive the second driving voltage ELVSS (see FIG. 5) via the first part PT1.

The thickness of the first conductive layer CDL1 may be thicker than that of the second conductive layer CDL2. For the first part PT1, a side surface of the second conductive layer CDL2 may further protrude toward the central direction of the light emitting area PXA than the side surface of the first conductive layer CDL1 to include a tip.

Each of the first conductive layer CDL1 and the second conductive layer CDL2 may include a conductive material. The first conductive layer CDL1 may include a material of first conductivity, and the second conductive layer CDL2 may include a material of second conductivity lower than the first conductivity.

Specifically, each of the first conductive layer CDL1 and the second conductive layer CDL2 may include a metal material. For example, the first conductive layer CDL1 may include aluminum, and the second conductive layer CDL2 may include titanium.

The light emitting element layer 140 may further include a protection pattern TPL. The protection pattern TPL may cover at least a portion of the top surface of the first electrode LE. The protection pattern TPL may prevent or reduce the first electrode LE from being damaged in an etching process for pattering the lower pixel definition layer LDL.

The light emitting element layer 140 may further include a capping layer CPL located on the second electrode UE. The capping layer CPL may serve to enhance the light emission efficiency according to the principle of constructive interference. The capping layer CPL may include a material having the refractive index of 1.6 or greater with respect to light of, for example, a wavelength of 589 nm. The capping layer CPL may be an organic capping layer including an organic material, an inorganic capping layer including an inorganic material, or a composite capping layer including organic and inorganic materials. For example, the capping layer may include a carbocyclic compound, a heterocyclic compound, an amine group-containing compound, a porphine derivative, a phthalocyanine derivative, a naphthalocyanine derivative, an alkali metal complex, an alkaline earth metal complex, or any combination thereof. The carbocyclic compound, the heterocyclic compound and the amine group-containing compound may be optionally substituted with a substituent including O, N, S, Se, Si, F, Cl, Br, I or any combination thereof.

Meanwhile, a dummy pattern may be located on the upper pixel definition layer UDL. The dummy pattern may include layers including the same materials as those included in the light emitting pattern EP located on the first electrode LE, the second electrode UE, and the capping layer CPL.

At least a portion of the dummy pattern may be covered by a first inorganic encapsulation layer 151 of the encapsulation layer 150 to be described below. In addition, the dummy pattern may include the slit SLT like the upper pixel definition layer UDL. Accordingly, the dummy pattern located on the first part PT1 may be electrically insulated from the dummy pattern located on the second part PT2.

The encapsulation layer 150 may be located on the light-emitting element layer 140. The encapsulation layer 150 may include the first inorganic encapsulation layer 151, an organic encapsulation layer 152 and a second inorganic encapsulation layer 153 that are sequentially laminated. The first and second inorganic encapsulation layers 151, 153 protect the light emitting element layer 140 from moisture and oxygen, and the organic encapsulation layer 152 may protect the light emitting element layer 140 from foreign matters such as dust particles.

According to some embodiments of the present disclosure, a low refractive layer may be further located between the capping layer CPL and the encapsulation layer 150. The low refractive layer may include Lithium fluoride. The low refractive layer may be provided by a thermal deposition method.

The sensor layer 200 may be located on the display layer 100. The sensor layer 200 may be referred to as a sensor, an input sensing layer, or an input sensing panel. The sensor layer 200 may include a sensor base layer 210, a first sensor conductive layer 220, a sensor insulation layer 230, a second sensor conductive layer 240, and a sensor cover layer 250.

The sensor base layer 210 may be directly located on the display layer 100. The sensor base layer 210 may be an inorganic layer including at least any one among silicon nitride, silicon oxynitride, or silicon oxide. Alternatively, the sensor base layer 210 may be an organic layer including an epoxy resin, an acrylic resin, or an imide-based resin. The sensor base layer 210 may have a single layer structure, or a multilayer structure laminated along the third direction DR3.

Each of the first sensor conductive layer 220 and the second sensor conductive layer 240 may have a single layer structure or a multilayer structure laminated along the third direction DR3.

The conductive layer of the single layer structure may include a metal layer or a transparent conductive layer. The metal layer may include molybdenum, silver, titanium, copper, aluminum, or an alloy thereof. The transparent conductive layer may include a transparent conductive oxide such as indium tin oxide, indium zinc oxide, zinc oxide, or indium-zinc-tin oxide. Besides, the transparent conductive layer may include a conductive polymer such as PEDOT, a metal nano-wire, or graphene.

The conductive layer of the multilayer structure may include metal layers. For example, the metal layers may have a three-layer structure of titanium/aluminum/titanium. The conductive layer of the multilayer structure may include at least one metal layer and at least one transparent conductive layer.

The sensor insulation layer 230 may be located between the first sensor conductive layer 220 and the second sensor conductive layer 240. The sensor insulation layer 230 may include an inorganic film. The inorganic film may include at least any one among aluminum oxide, titanium oxide, silicon oxide, silicon oxynitride, zirconium oxide, or halfnium oxide.

The sensor insulation layer 230 may include an organic film. The organic film may include at least one among an acrylic-based resin, a methacrylic-based resin, polyisoprene, a vinyl-based resin, an epoxy-based resin, a urethane-based resin, a cellulose-based resin, a siloxane-based resin, a polyimide based-resin, a polyamide-resin, or a parylene-based resin.

The sensor cover layer 250 may be located on the sensor insulation layer 230 and cover the second sensor connective layer 240. The second sensor conductive layer 240 may include a conductive pattern. The sensor cover layer 250 may cover the conductive pattern, and reduce or remove a probability that the conductive pattern 240P will be damaged in a subsequent process. The sensor cover layer 250 may include an inorganic material. For example, the sensor cover layer 250 may include silicon nitride, but is not particularly limited thereto. According to some embodiments of the present disclosure, the sensor cover layer 250 may be omitted.

The anti-reflection layer 300 may be located on the sensor layer 200. The anti-reflection layer 300 may include a division layer 310, a plurality of color filters 320, and a planarization layer 330.

The division layer 310 may be arranged to overlap the conductive pattern of the second sensor conductive layer 240. The sensor cover layer 250 may be located between the division layer 310 and the second sensor conductive layer 240. The division layer 310 may prevent or reduce reflection of external light due to the second conductive layer 240. A material constituting the division layer 310 may not be particularly limited if the material absorbs light. The division layer 310 is a layer having a black color, and, according to some embodiments, may include a black coloring agent. The black coloring agent may include a black dye or a black pigment. The black coloring agent may include carbon black, a metal such as chromium, or an oxide thereof.

A divided opening 310op may be defined in the division layer 310. The divided opening 310op may overlap the light emitting layer EL. The color filters 320 may be arranged corresponding to the divided opening 310op. The color filters 320 may transmit light provided from the light emitting layer EL overlapping the color filter 320.

The planarization layer 330 may cover the division layer 310 and the color filters 320. The planarization layer 330 may include an organic material, and provide a planar surface on the top surface of the planarization layer 330. According to some embodiments of the present disclosure, the planarization layer 330 may be omitted.

According to some embodiments of the present disclosure, the anti-reflection layer 300 may include a reflection adjustment layer instead of the color filters 320. For example, the color filters 320 may be omitted in FIG. 6, and the reflection adjustment layer may be added to the position where the color filters 320 are omitted. The reflection adjustment layer may selectively absorb light in a partial band of light reflected inside a display panel and/or an electronic apparatus or light incident from the outside of the display panel and/or the electronic apparatus.

As an example, the reflection adjustment layer may absorb light in a first wavelength band of about 490 nm to about 505 nm and in a second wavelength band of about 585 nm to about 600 nm to cause the light transmittance to be about 40% or less in the first wavelength band and the second wavelength band. The reflection adjustment layer may absorb light of wavelengths outside wavelength ranges of red, green, and blue light emitted from the light emitting layer EL. In this way, the reflection adjustment layer may absorb light of wavelengths that do not belong to the red, green, or blue light emitted from the light emitting layer EL, and thus prevent, reduce, or minimize the luminance of the display panel and/or electronic apparatus from being reduced. In addition, degradation of the light emission efficiency of the display panel and/or electronic apparatus may also be prevented, reduced, or minimized, and the visibility may be relatively improved.

The reflection adjustment layer may be provided with an organic material layer including a dye, a pigment, or a combination thereof. The reflection adjustment layer may include a Tetraazaporphyrin (TAP)-based compound, a Porphyrin-based compound, a Metal Porphyrin-based compound, an Oxazine-based compound, a Squarylium-based compound, a Triarylmethane-based compound, a Polymethine-based compound, an anthraquinone-based compound, a Phthalocyanine-based compound, an azo-based compound, a perylene-based compound, a Xanthene-based compound, a diimmonium-based compound, a Dipyrromethene-based compound, a Cyanine-based compound, or a combination thereof.

According to some embodiments, the reflection adjustment layer may have the light transmittance of about 64% to about 72%. The light transmittance of the reflection adjustment layer may be adjusted according to the content of the dye and/or the pigment included in the reflection adjustment layer.

According to some embodiments of the present disclosure, the reflection adjustment layer 300 may include a phase retarder and/or a polarizer. The reflection adjustment layer 300 may include at least a polarization film. In this case, the reflection adjustment layer 300 may be attached to the sensor layer 200 via an adhesive layer.

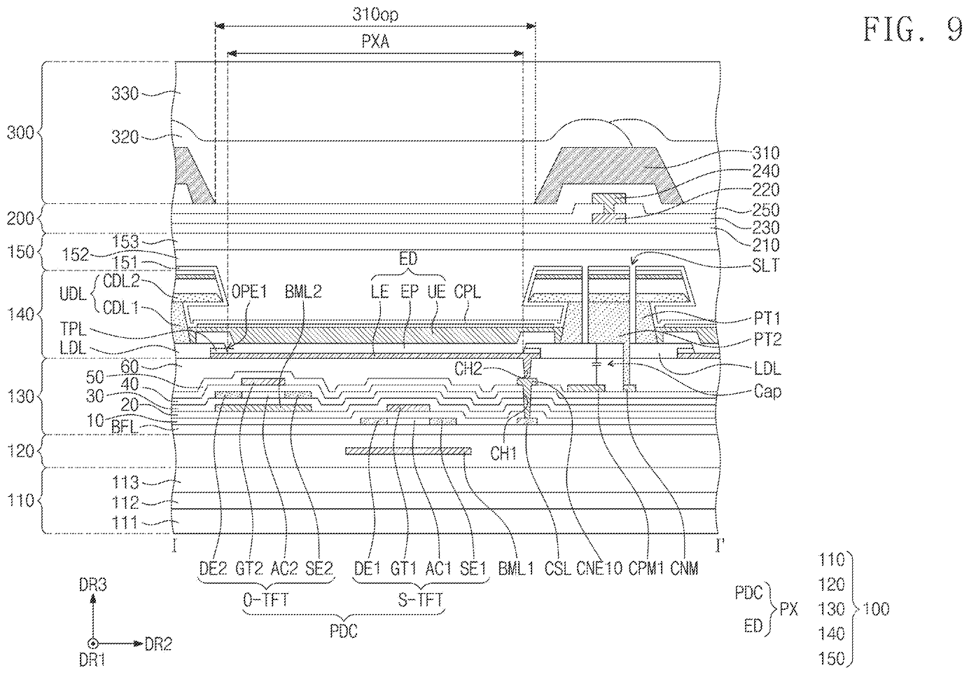

FIG. 9 is a cross-sectional view of the display panel DP according to some embodiments of the present disclosure. FIG. 9 may be another example cross-sectional view taken along a line I-I′ of FIG. 4. In addition, FIG. 9 may be another example cross-sectional view taken along a line I-I′ of FIG. 7.

Referring to FIG. 7, each of the sixth insulation layer 60 and the lower pixel definition layer LDL may overlap at least a portion of the second part PT2 in a plan view. The insulating layer 60 and the lower pixel definition layer LDL may include an opening through which the second part PT2 may contact the connection metal CNM. The second part PT2 and the first cap metal CPM1 may constitute the first capacitor Cst (see FIG. 5) having cap capacity Cap.

In comparison to the case in FIG. 6 where the first cap metal CPM1 is exposed by the opening 60-OP of the sixth insulation layer 60 to contact the lower pixel definition layer LDL, a case shown in FIG. 9 may have a larger space between the second part PT2 and the first cap metal CPM1. Accordingly, the cap capacity Cap may be small.

For the signal delivery by the pixel circuit, the content described above with reference to FIGS. 8A and 8B may be identically applied.

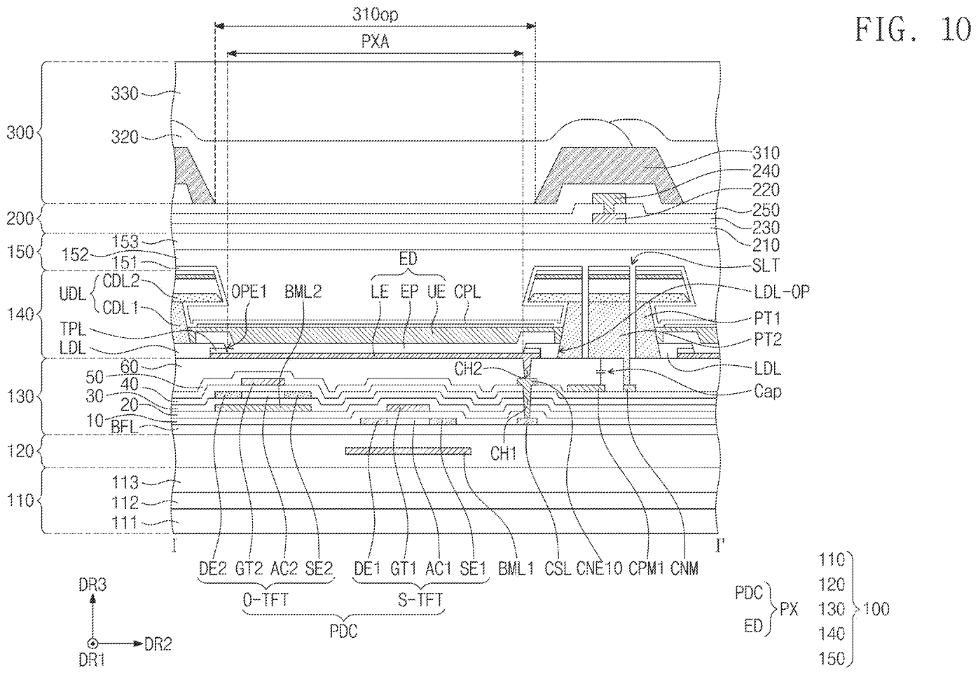

FIG. 10 is a cross-sectional view of the display panel DP according to some embodiments of the present disclosure. FIG. 10 may be another example cross-sectional view taken along a line I-I′ of FIG. 4. In addition, FIG. 10 may be another example cross-sectional view taken along a line I-I′ of FIG. 7.

Referring to FIG. 10, an opening LDL-OP may be defined in the lower pixel definition layer LDL. The second part PT2 may contact at least one insulation layer exposed by the opening LDL-OP of the lower pixel definition layer LDL. For example, the second part PT2 may contact the sixth insulation layer 60.

The second part PT2 and the first cap metal CPM1 may constitute the first capacitor Cst (see FIG. 5) having cap capacity Cap. The distance between the second part PT2 and the first cap metal CPM1 in FIG. 10 may be different from those in FIGS. 6 and 9, and accordingly, the cap capacity Cap may also be different.

In addition, the sixth insulation layer 60 may include an opening so that the second part PT2 can contact the connection metal CNM.

For the signal delivery by the pixel circuit, the content described above with reference to FIGS. 8A and 8B may be identically applied.

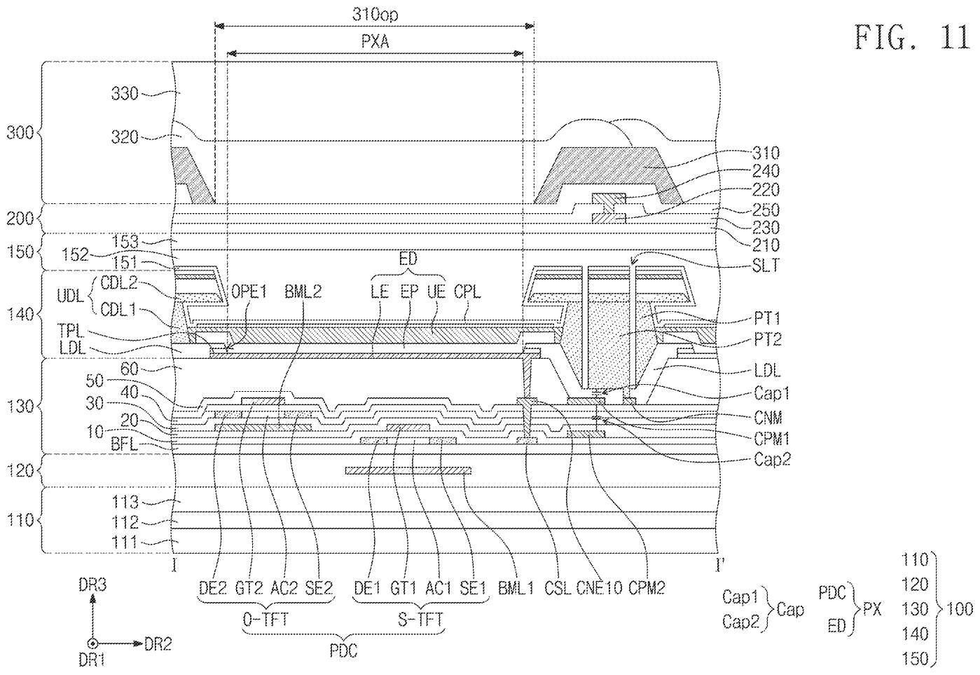

FIG. 11 is a cross-sectional view of the display panel DP according to some embodiments of the present disclosure. FIG. 11 may be another example cross-sectional view taken along a line I-I′ of FIG. 4. In addition, FIG. 11 may be another example cross-sectional view taken along a line I-I′ of FIG. 7.

Referring to FIG. 11, the circuit layer 130 may further include a second cap metal CPM2 located under the first cap metal CPM1. In FIG. 11, the second cap metal CPM2 is shown located on the top surface of the first insulation layer 10, but is not limited thereto. For example, the second cap metal CPM2 may also be located between the second insulation layer 20 and the third insulation layer 30, or between the third insulation layer 30 and the fourth insulation layer 40.

The second cap metal CPM2 may overlap at least a portion of the first part CPM1 in a plan view. The second part PT2, the first cap metal CPM1, and the second cap metal CPM2 may constitute the first capacitor Cst 5 having cap capacity Cap. In this case, the cap capacity Cap may be calculated as the sum of first cap capacity Cap1 due to the second part PM2 and the first cap metal CPM1 and second cap capacity Cap2 due to the second cap metal CPM2. In other words, according to some embodiments, a triple cap structure is applied, and thus identical cap capacity Cap with a smaller area may be implemented in comparison to FIG. 6.

In addition, the sixth insulation layer 60 may include an opening so that the second part PT2 can contact the connection metal CNM.

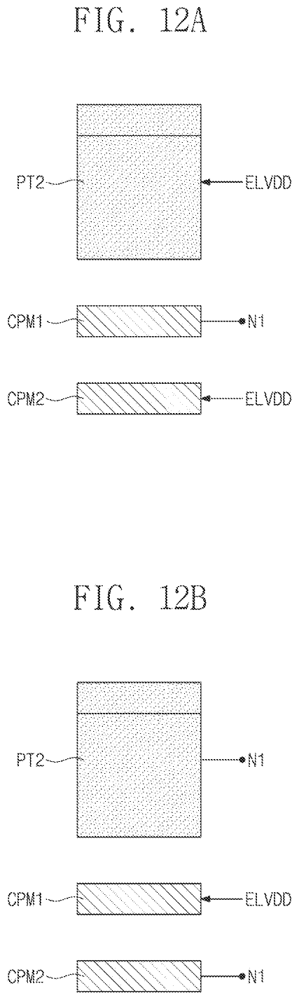

FIGS. 12A and 12B are respective schematic diagrams of signals according to some embodiments of the present disclosure. FIGS. 12A and 12B may be respective schematic diagrams showing the example signals of the first capacitor Cst of the display panel DP of FIG. 11.

Referring to FIGS. 5 and 12A, each of the second part PT2 and the second cap metal CPM2 may be the first capacitor electrode Cst1 connected to the driving voltage line VL1 to which the driving voltage ELVDD is provided, and the first cap metal CPM1 may be the second capacitor electrode Cst2 connected through the first node N1 to the gate electrode of the driving transistor T1 that is the driving transistor.

On the contrary, referring to FIGS. 5 and 12B, the second part PT2 and the second cap metal CPM2 may be the second capacitor electrode Cst2 connected through the first node N1 to the gate electrode of the first transistor T1 that the driving transistor, and the first cap metal CPM1 may be the first capacitor electrode Cst1 connected to the driving voltage line VL1 to which the driving voltage ELVDD is provided.

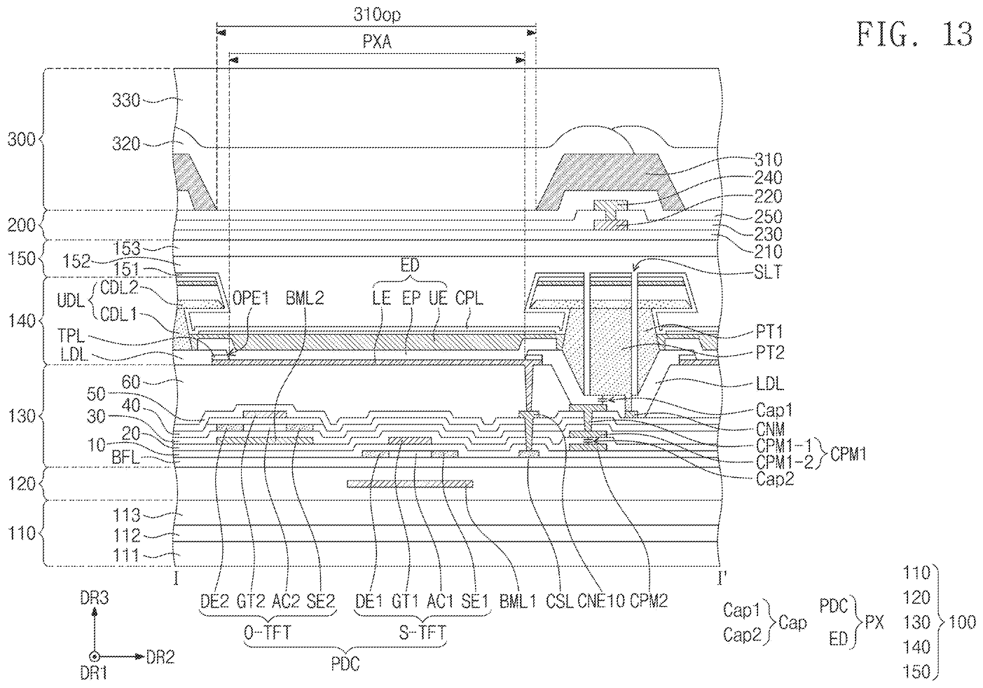

FIG. 13 is a cross-sectional view of the display panel DP according to some embodiments of the present disclosure. FIG. 13 may be another example cross-sectional view taken along a line I-I′ of FIG. 4. In addition, FIG. 13 may be another example cross-sectional view taken along a line I-I′ of FIG. 7.

Referring to FIG. 13, the first cap metal CPM1 may include a 1-1st cap metal CPM1-1 and a 1-2nd cap metal CPM1-2 located on a different layer from the 1-1st cap metal CPM1-1. The 1-2nd cap metal CPM1-2 may be electrically connected to the 1-1st cap metal CPM1-1.

As the 1-2nd cap metal CPM1-2 is located on the different layer from the 1-1st cap metal CPM1-1, the substantial thickness of the first cap metal CPM1 may become thick. In addition, the distance between the first cap metal CPM1 and the second cap metal CPM2 may become smaller, and the second cap capacity Cap2 may increase.

According to the above-described, the display panel according to the present disclosure may reduce the area of the pixel circuit according to that the second portion of the upper pixel definition layer constitutes the pixel circuit.

While the present invention has been described with reference to some example embodiments thereof, it will be clear to those of ordinary skill in the art to which the invention pertains that various changes and modifications may be made to the described embodiments without departing from the spirit and technical area of the invention as defined in the appended claims and their equivalents.

Thus, the scope of embodiments according to the present disclosure shall not be restricted or limited by the foregoing description, but be determined by the broadest permissible interpretation of the following claims, and their equivalents.

What is claimed is:

1. A display panel comprising:
a base layer;
a circuit layer on the base layer and comprising a pixel circuit; and
a light emitting element layer on the circuit layer,
wherein the light emitting element layer comprises:
a first electrode on the circuit layer;
a light emitting pattern on the first electrode;
a second electrode on the light emitting pattern; and
an upper pixel definition layer on the circuit layer and having an upper opening defined therein,
the upper pixel definition layer comprises a first part electrically connected to the second electrode and a second part electrically insulated from the first part, and
the second part is surrounded by the first part in a plan view.

2. The display panel according to claim 1, wherein the circuit layer further comprises a connection metal electrically connected to the second part.

3. The display panel according to claim 1, wherein the light emitting element layer further comprises a lower pixel definition layer under the upper pixel definition layer and having a light emitting area defined therein.

4. The display panel according to claim 3, wherein the circuit layer further comprises a first cap metal under the second part and overlapping at least a portion of the second part in a plan view.

5. The display panel according to claim 4, wherein the pixel circuit comprises:
a driving transistor; and
a capacitor connected between a gate electrode of the driving transistor and a driving voltage line to which a driving voltage is provided, and
the second part and the first cap metal constitutes the capacitor.

6. The display panel according to claim 5, wherein the circuit layer further comprises at least one insulation layer under the first electrode and under the lower pixel definition layer, and
each of the at least one insulation layer and the lower pixel definition layer overlaps at least a portion of the second part in a plan view.

7. The display panel according to claim 6, wherein an opening is defined in the lower pixel definition layer, and the second part contacts the at least one insulation layer exposed by the opening of the lower pixel definition layer.

8. The display panel according to claim 6, wherein an opening is defined in at least one insulation layer, and the lower pixel definition layer contacts the first cap metal exposed by the opening of the at least one insulation layer.

9. The display panel according to claim 8, wherein a distance between the first cap metal and the first part is larger than that between the first cap metal and the second part.

10. The display panel according to claim 4, wherein the circuit layer further comprises a second cap metal overlapping at least a portion of the first cap metal in a plan view and under the first cap metal.

11. The display panel of claim 10, wherein an identical signal is provided to the second cap metal and the second part.

12. The display panel of claim 10, wherein the first cap metal comprises a 1-1st cap metal, and a 1-2nd cap metal connected to the 1-1st cap metal and on a different layer from the 1-1st cap metal.

13. The display panel according to claim 1, further comprising:
an encapsulation layer comprising an organic encapsulation layer and on the light emitting element layer,
wherein the organic encapsulation layer fills a space between the first part and the second part and covers the light emitting element layer.

14. The display panel according to claim 3, wherein the upper pixel definition layer comprises a first conductive layer and a second conductive layer on the first conductive layer.

15. The display panel according to claim 14, wherein, in the first part, a side surface of the second conductive layer protrudes further toward a central direction of the light emitting area than a side surface of the first conductive layer.

16. The display panel according to claim 1, further comprising a protection pattern configured to cover at least a portion of a top surface of the first electrode.

17. A display panel comprising:
a base layer;
a circuit layer on the base layer and comprising a pixel circuit;
a light emitting element layer on the circuit layer; and
an encapsulation layer on the light emitting element layer,
wherein the pixel circuit comprises:
a driving transistor; and
a capacitor connected between a gate electrode of the driving transistor and a driving voltage line configured to receive a driving voltage,
the light emitting element layer comprises:
a first electrode on the circuit layer and electrically connected to the pixel circuit;
a light emitting pattern on the first electrode;
a second electrode on the light emitting pattern; and
an upper pixel definition layer on the circuit layer and having an upper opening defined therein, and
the upper pixel definition layer comprises a first part electrically connected to the second electrode and a second part constituting the capacitor.

18. The display panel according to claim 17, wherein a slit is defined between the first part and the second part of the upper pixel definition layer, and a shape of the slit is a polygon or a ring in a plan view.

19. The display panel according to claim 18, wherein the encapsulation layer comprises an organic encapsulation layer, and the slit is filled with the organic encapsulation layer.

20. The display panel according to claim 17, wherein the circuit layer further comprises a connection metal electrically connected to the second part.
